(19) United States
(12) Patent Application Publication
(10) Pub. No.: US 2025/0318221 A1
(43) Pub. Date: Oct. 9, 2025

(54) SEMICONDUCTOR DEVICE

(71) Applicants: Kabushiki Kaisha Toshiba, Tokyo (JP); Toshiba Electronic Devices & Storage Corporation, Tokyo (JP)

(72) Inventors: Hiroaki KATOU, Nonoichi Ishikawa (JP); Hirofumi KAWAI, Nonoichi Ishikawa (JP); Saya FUJINO, Kanazawa Ishikawa (JP); Takuya YASUTAKE, Kanazawa Ishikawa (JP); Hyuga SAITO, Nonoichi Ishikawa (JP); Atsushi KITO, Nonoichi Ishikawa (JP)

(21) Appl. No.: 18/829,252

(22) Filed: Sep. 9, 2024

(30) Foreign Application Priority Data
Apr. 8, 2024 (JP) 2024-062405

(51) Int. Cl. H01L 29/06; H01L 29/40; H01L 29/417; H01L 29/78

(52) U.S. Cl. CPC H10D 62/127; H10D 30/668; H10D 64/117; H10D 64/252

(57) ABSTRACT

A semiconductor device according to the present embodiment includes a semiconductor area, a first electrode, a second electrode, a control electrode, and a third electrode. The semiconductor area includes a first semiconductor layer of a first conductivity type and a second semiconductor layer of a second conductivity type. The semiconductor area further includes a fourth semiconductor layer of the second conductivity type provided between the second semiconductor layer and the second electrode and electrically connected to the second electrode. A distance between the second semiconductor layer, which is in contact with the fourth semiconductor layer, and the first electrode, in a second region surrounding the first region is smaller than a distance between the second semiconductor layer, which is in contact with the fourth semiconductor layer, and the first electrode, in the first region.

### CROSS REFERENCE TO RELATED APPLICATIONS

This application is based upon and claims the benefit of priority from the prior Japanese Patent Application No. 2024-062405, filed on Apr. 8, 2024, the entire contents of which are incorporated herein by reference.

### FIELD

The embodiments of the present invention relate to a semiconductor device.

### BACKGROUND

A termination region of an FPMOS (field plate metal-oxide-semiconductor) may have a low avalanche resistance and is likely to be destroyed. The termination region is a region other than a cell region where a current flows through a channel.

### BRIEF DESCRIPTION OF THE DRAWINGS

FIG. 1 is a schematic cross sectional view showing a semiconductor device according to a first embodiment;

FIG. 2 is a schematic layout diagram showing the semiconductor device according to the first embodiment;

FIG. 3 is a schematic cross sectional view showing the semiconductor device according to the first embodiment;

FIG. 4 is as schematic cross sectional view showing a semiconductor device according to a second embodiment;

FIG. 5 is a schematic layout diagram showing a semiconductor device according to a third embodiment; and

FIG. 6 is a schematic layout diagram showing a semiconductor device according to a fourth embodiment.

### DETAILED DESCRIPTION

Embodiments will now be explained with reference to the accompanying drawings. The present invention is not limited to the embodiments. It should be noted that the drawings are schematic or conceptual, and the relationship between the thickness and the width in each element and the ratio among the dimensions of elements do not necessarily match the actual ones. Even if two or more drawings show the same portion, the dimensions and the ratio of the portion may differ in each drawing. In the present specification and the drawings, elements identical to those described in the foregoing drawings are denoted by like reference characters and detailed explanations thereof are omitted as appropriate.

The semiconductor device according to this embodiment includes a semiconductor area, a first electrode, a second electrode, a control electrode, and a third electrode. The semiconductor area includes a first semiconductor layer of a first conductivity type and a second semiconductor layer of a second conductivity type. The first electrode is provided on the back surface of the semiconductor area. The second electrode is provided on the front surface of the semiconductor area. The first semiconductor layer extends between the first electrode and the second electrode, and the second semiconductor layer is provided between the first semiconductor layer and the second electrode. The control electrode is provided within the semiconductor area. The third electrode is located between the control electrode and the first electrode in a first direction from the first electrode toward the second electrode. The semiconductor area in a first region further includes a third semiconductor layer of the first conductivity type provided between the second semiconductor layer and the second electrode. The semiconductor area further includes a fourth semiconductor layer of the second conductivity type provided between the second semiconductor layer and the second electrode and electrically connected to the second electrode. The distance between the second semiconductor layer, which is in contact with the fourth semiconductor layer, and the first electrode, in the second region surrounding the first region is smaller than the distance between the second semiconductor layer, which is in contact with the fourth semiconductor layer, and the first electrode, in the first region.

The arrangement and configuration of each portion will be described using the X-axis, Y-axis, and Z-axis shown in each figure. The X-axis, Y-axis, and Z-axis are mutually orthogonal and respectively represent the X-direction, Y-direction, and Z-direction. The Z-direction may be described as the upward direction and the opposite direction as the downward direction.

### First Embodiment

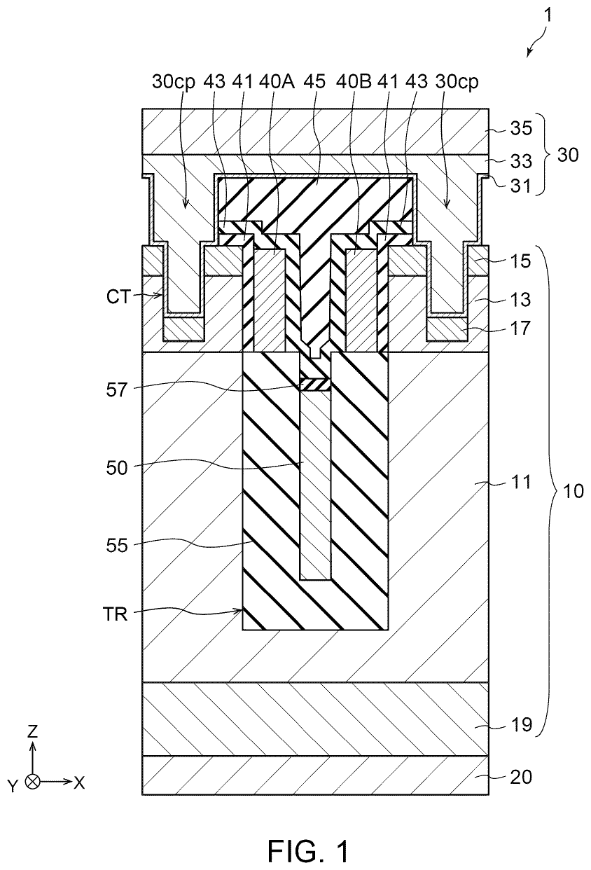

FIG. 1 is a schematic cross sectional view showing a semiconductor device 1 according to a first embodiment. The semiconductor device 1 is, for example, a MOSFET. The semiconductor device 1 has a trench gate structure. The semiconductor device 1 includes a semiconductor area 10, a first electrode 20, a second electrode 30, a control electrode 40, and a third electrode 50. The semiconductor area 10 is, for example, silicon.

The semiconductor area 10 has, for example, a back surface on which the first electrode 20 is provided, and a front surface opposite thereto. The second electrode 30 is provided on a front surface side of the semiconductor area 10. The first electrode 20 is a drain electrode. The first electrode 20 is provided on the back surface of the semiconductor area 10. The second electrode 30 is a source electrode.

The semiconductor area 10 includes a first semiconductor layer 11 of a first conductivity type, a second semiconductor layer 13 of a second conductivity type, a third semiconductor layer 15 of the first conductivity type, a fourth semiconductor layer 17 of the second conductivity type, and a fifth semiconductor layer 19 of the first conductivity type. For example, the first conductivity type is n-type, and the second conductivity type is p-type.

The first semiconductor layer 11 is a so-called drift layer. The first semiconductor layer 11 extends between the first electrode 20 and the second electrode 30.

The second semiconductor layer 13 is a so-called p-type diffusion layer. The second semiconductor layer 13 is provided between the first semiconductor layer 11 and the second electrode 30.

The third semiconductor layer 15 is a so-called n-type source layer. The third semiconductor layer 15 is provided between the second semiconductor layer 13 and the second electrode 30. The third semiconductor layer 15 contains a first conductivity type impurity at a higher concentration than the first semiconductor layer 11, and is electrically connected to the second electrode 30.

The fourth semiconductor layer 17 is a so-called p-type contact layer. The fourth semiconductor layer 17 is provided between the second semiconductor layer 13 and the second electrode 30. The fourth semiconductor layer 17 contains a second conductivity type impurity at a higher concentration than the second semiconductor layer 13, and is electrically connected to the second electrode 30. In this example, the fourth semiconductor layer 17 is provided in the second semiconductor layer 13. The second semiconductor layer 13 is electrically connected to the second electrode 30 via the fourth semiconductor layer 17.

The fifth semiconductor layer 19 is a so-called n-type drain layer. The fifth semiconductor layer 19 is provided between the first semiconductor layer 11 and the first electrode 20. The fifth semiconductor layer 19 contains a first conductivity type impurity at a higher concentration than the first semiconductor layer 11, and is electrically connected to the first electrode 20.

The control electrode 40 is a gate electrode. The control electrode 40 is provided inside a trench TR that is located between the first electrode 20 and the second electrode 30, and provided in the semiconductor area 10. The third electrode 50 is a so-called field plate. The third electrode 50 is electrically connected to the second electrode 30, and is provided inside the trench TR together with the control electrode 40.

As shown in FIG. 1, the control electrode 40 is provided at the same level as the second semiconductor layer 13 in the direction from the first electrode 20 toward the second electrode 30, for example, in the Z direction. The control electrode 40 includes a first controller 40A and a second controller 40B. The first controller 40A and the second controller 40B are lined up inside the trench TR in a direction along the boundary between the first semiconductor layer 11 and the second semiconductor layer 13, for example, in the X direction.

The trench TR extends in a direction from the second electrode 30 toward the first electrode 20, and has a depth that reaches from the front surface side of the semiconductor area 10 into the first semiconductor layer 11. The third electrode 50 is provided, for example, so as to be located in the first semiconductor layer 11. In the trench TR, the distance from the third electrode 50 to the first electrode 20 is shorter than the distance from the control electrode 40 to the first electrode 20.

As shown in FIG. 1, the semiconductor device 1 further includes a first insulation film 41, a second insulation film 43, a third insulation film 45, a fourth insulation film 55, and a fifth insulation film 57.

The first insulation film 41 is a so-called gate insulation film. The first insulation film 41 is provided between the semiconductor area 10 and the control electrode 40, and electrically insulates the control electrode 40 from the semiconductor area 10. The second semiconductor layer 13 is provided so as to face the control electrode 40 via the first insulation film 41. The third semiconductor layer 15 is in contact with the first insulation film 41 between the second semiconductor layer 13 and the second electrode 30.

A plurality of trenches TR are provided, and are lined up, for example, in the X direction. The second semiconductor layer 13 is provided between the plurality of trenches TR, and faces the first controller 40A and the second controller 40B of the control electrode 40 via the first insulation film 41.

The second insulation film 43 is provided inside the trench TR so as to cover the first controller 40A and the second controller 40B of the control electrode 40.

The third insulation film 45 is provided between the second electrode 30 and the control electrode 40, and electrically insulates the control electrode 40 from the second electrode 30. The second insulation film 43 is located between the control electrode 40 and the third insulation film 45. The third insulation film 45 has a first portion located between the first controller 40A of the control electrode 40 and the second electrode 30, a second portion located between the second controller 40B and the second electrode 30, and a third portion extending between the first controller 40A and the second controller 40B.

The second insulation film 43 and the third insulation film 45 serves as an interlayer insulation film that electrically insulates the control electrode 40 from the second electrode 30.

The fourth insulation film 55 is provided between the semiconductor area 10 and the third electrode 50, and electrically insulates the third electrode 50 from the semiconductor area 10. The third electrode 50 is located, for example, in the first semiconductor layer 11, and the fourth insulation film 55 is located between the first semiconductor layer 11 and the third electrode 50.

The fourth insulation film 55 is provided, for example, so as to contact the control electrode 40. Each of widths in the X direction of the portions where the fourth insulation film 55 is in contact with the control electrode 40 is wider than the width in the X direction of the first controller 40A of the control electrode 40 and wider than the width in the X direction of the second controller 40B thereof. The third insulation film 45 faces the fourth insulation film 55 via the second insulation film 43.

The fifth insulation film 57 is provided between the third portion of the third insulation film 45 and the third electrode 50. The second insulation film 43 includes a portion that is located between the third portion of the third insulation film 45 and the fifth insulation film 57. The portion of the second insulation film 43 located between the third portion of the third insulation film 45 and the fifth insulation film 57 is located between the portion of the fourth insulation film 55 that is in contact with the first controller 40A and the portion of the fourth insulation film 55 that is in contact with the second controller 40B.

As shown in FIG. 1, the second electrode 30 includes a first metal layer 31, a second metal layer 33, and a third metal layer 35. The first metal layer 31 is provided on the third insulation film 45. The second metal layer 33 and the third metal layer 35 are stacked in this order on the first metal layer 31.

The first metal layer 31 serves as a so-called barrier layer that prevents diffusion of metal atoms into the semiconductor area 10. The second metal layer 33 is filled inside the contact trench CT that extends from the third insulation film 45 to the semiconductor area 10. The second metal layer 33 is provided as a so-called buried layer. The third metal layer 35 is provided as a so-called bonding layer, and is to be connected to a conductor such as a metal wire.

The second electrode 30 includes contactors 30cp extending from the upper surface of the third insulation film 45 into the semiconductor area 10. Each contactor 30cp is in contact with and electrically connected to the third semiconductor layer 15 and the fourth semiconductor layer 17 on the inner surface of the contact trench CT.

In the first embodiment, the third electrode 50 has a first end on the first electrode 20 side and a second end on the second electrode 30 side. The second end of the third electrode 50 is located, in the Z direction, below the level of the boundary between the control electrode 40 and the fourth insulation film 55, for example. The third electrode 50 is provided so as not to overlap with the control electrode 40, for example, when viewed in the X direction. Note that the first embodiment is not limited to this, and the second end of the third electrode 50 may be located between the first controller 40A and the second controller 40B of the control electrode 40.

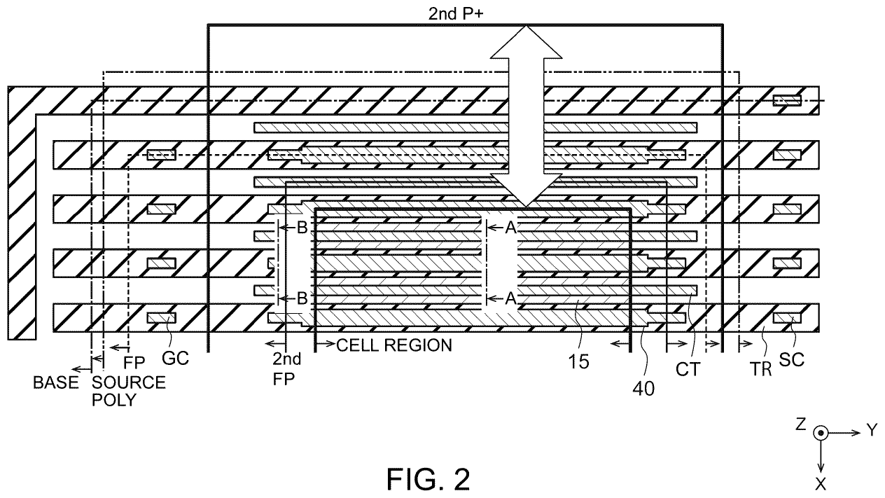

FIG. 2 is a schematic layout diagram showing the semiconductor device 1 according to the first embodiment. FIG. 1 is a cross sectional view taken along a line A-A in FIG. 2.

FIG. 2 shows a partial region in the termination portion of the semiconductor device 1.

As shown in FIG. 2, the trenches TR and the contact trenches CT extend in the Y direction.

The source contactors SC each electrically connect the third electrode 50, drawn out to the termination region, to the second electrode 30, which is the source electrode.

The gate contactors GC each electrically connect the control electrode 40, drawn out to the termination region, to a gate wire (not shown).

The first region (cell region or effective cell region) is a region where the third semiconductor layer 15 is provided. The cell region is the region where a current flows through each channel. The line A-A shown in FIG. 2 is inside the cell region.

The second region (termination region) surrounding the cell region is a region where no third semiconductor layer 15 is provided. The termination region is the region other than the cell region.

A base region (a region outside a dash-dot line shown in FIG. 2) is a region related to formation of a mask in photolithography for forming second semiconductor layer 13.

A source poly region (a region outside a dash-dot-dot line shown in FIG. 2) is a region related to formation of a mask in photolithography for forming each source contactor SC by partially shallowing the etching of the third electrode 50 within the chip of the semiconductor device 1. The source poly region is a region that protects each third electrode 50 when the third electrode 50 is etched.

An FP region (outside the dashed line shown in FIG. 2) is a region related to formation of a mask in photolithography to keep and protect the fourth insulation film 55 in the termination portion in the Y-direction of each trench TR when the fourth insulation film 55 is removed in the region where the control electrode 40 is formed. The FP region is a region where no control electrode 40 is formed.

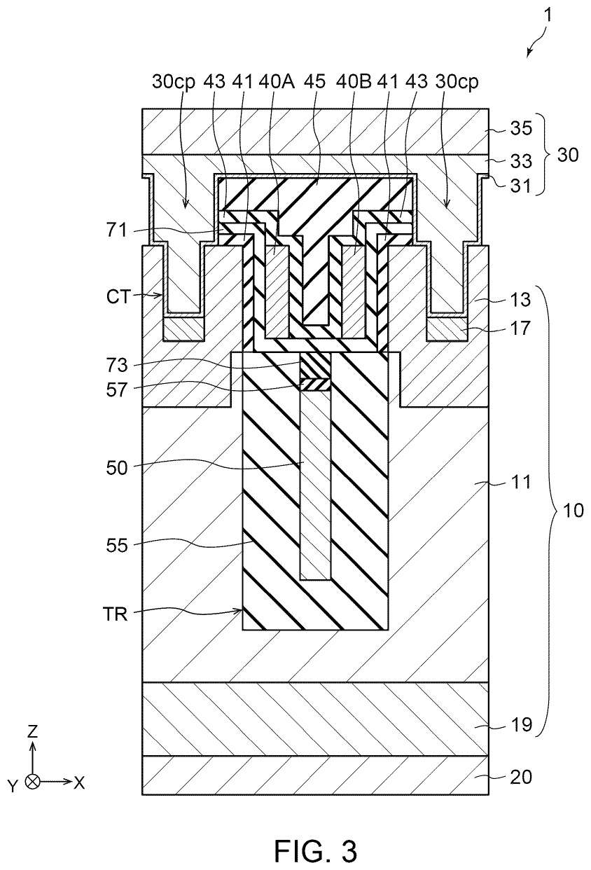

A 2nd FP region (outside the thin solid lines in FIG. 2) is a region for forming a mask in photolithography to form each seventh insulation film 71. Details of the seventh insulation film 71 will be described later with reference to FIG. 3. The seventh insulation film 71 is provided in the 2nd FP region. The 2nd FP region surrounds the cell region, that is, the third semiconductor layer 15 and its vicinity.

A 2nd P+ region (the region sandwiched between thick solid lines in FIG. 2) is a region into which a high concentration of impurity of the second conductivity type (p-type) is implanted. The details of the implantation of the high concentration of impurity of the second conductivity type will be described later with reference to FIG. 3. The 2nd P+ region does not overlap the cell region, and surrounds it.

Next, the details of each fourth semiconductor layer 17 will be described.

The fourth semiconductor layer 17 provided at the bottom of the contact trench CT is provided for, for example, the following two purposes. The first is to fix the base to zero V by ohmic connection between the second semiconductor layer 13 (base) and the third semiconductor layer 15 (source). The second is to prevent the operation of the parasitic bipolar transistor. At a time of avalanche breakdown, holes are extracted from the bottom of the contact trench CT. At that time, if a voltage drop occurs at the base resistance Rb and the second semiconductor layer 13 rises to a level exceeding 0.5 V, a parasitic bipolar transistor will operate in which the third semiconductor layer 15 (source), the second semiconductor layer 13 (base), and the first semiconductor layer 11 respectively are the emitter, base, and collector, and the element will be destroyed. To prevent this, a high concentration of impurity of the second conductivity type (p type) is implanted into the bottom of each contact trench CT, and then a p diffusion layer is expanded around it by heat treatment to lower the base resistance Rb.

Next, the trade-off between avalanche resistance and on-resistance in the cell region will be explained.

When a high concentration of impurity of the second conductivity type (p type) is implanted and subjected to heat treatment to improve the avalanche resistance, the following problems may arise. The fourth semiconductor layer 17 may expand due to heat and reach the channel portion. In that case, the threshold value increases and the on-resistance deteriorates. In the example shown in FIG. 1, the fourth semiconductor layer 17 is formed in the center of the mesa portion between the trenches TR, but in reality, there is a “misalignment”. This makes the problem of the threshold increase even more serious. It can be said that the trade-off between avalanche resistance and on-resistance (threshold increase) determines the limit of cell pitch shrink.

If the product cannot be manufactured without avalanche resistance, the following measures may be taken even at the expense of on-resistance.

The first measure is, for example, to make the impurity of the second conductivity type more concentrated or implanted deeper at the bottom of each contact trench CT (fourth semiconductor layer 17). However, if an excessively high concentration of the second conductivity type impurity is implanted deep, the concentration will be high up to the lower end of the second semiconductor layer 13. This will strengthen the electric field near the lower end of the second semiconductor layer 13 when the DS (drain-source) breakdown voltage is measured, resulting in a decreased breakdown voltage. Therefore, this method has its limitation.

The second measure is to implant a relatively low concentration of impurity of the second conductivity type from the bottom of each contact trench CT, and then anneal it, so that the impurity concentration is lower and about the same as that of the second semiconductor layer 13. Here, the relatively low concentration is lower than the impurity concentration of the fourth semiconductor layer 17 and higher than the impurity concentration of the second semiconductor layer 13. As a result, for example, a structure is obtained in which the second semiconductor layer 13 in the cell region extends into the first semiconductor layer 11. In this structure, the operation of the parasitic bipolar transistor is further prevented. This may be because: the path widens in which the holes move toward the contact trench CT, reducing the resistance; or the thickness of the base of the parasitic bipolar transistor increases. However, the on-resistance deteriorates for the following reason. The reason for the deterioration of the on-resistance is that the current path in a state of on is narrower compared to the structure in which the fourth semiconductor layer 17 is widened by heat as described above. Furthermore, since there is a “misalignment”, the on-resistance of the side where the current path is narrowed due to the misalignment even more deteriorates.

Next, the termination region will be described.

As shown in FIG. 2, there are regions where no contact trench CT is provided in the +Y direction from the right end of the contact trenches CT and in the −Y direction from the left end of the contact trenches CT. In each region, when a surge enters from the back surface at the moment of turning off, for example, it is likely that a displacement current will flow into the second semiconductor layer 13 through the junction capacitance between the second semiconductor layer 13 and the first semiconductor layer 11, and the potential of the second semiconductor layer 13 will rise. This occurs because the contact trench CT is not located nearby and the potential is not fixed sufficiently. As a result, the parasitic bipolar transistor operates and the element may be destroyed.

In order to prevent the operation of the parasitic bipolar transistor in the termination region, it is conceivable to form a p-type high concentration layer (guard ring diffusion layer) in the regions where no contact trench CT is formed. The p-type high concentration layer contains a higher concentration of p-type impurity than the p-type impurity (second conductivity type impurity) of the second semiconductor layer 13. The p-type high concentration layer reduces the resistance and prevents the rise in potential, making it less likely that the element at the termination will be destroyed.

However, even if a p-type high concentration layer is formed in the entire termination region, the locations close to the third semiconductor layer 15 are important locations, and need to be more appropriately prevented from the potential rise.

Therefore, in the first embodiment, processing for improving the avalanche resistance (preventing operation of the parasitic bipolar transistor) is performed in the termination region. However, no processing for improving the avalanche resistance is performed in the cell region. In the termination region, no current flows through the channel, so the problem of a rise in on-resistance does not arise. This makes it possible to improve the avalanche resistance in the termination region near the third semiconductor layer 15 while preventing the rise in on-resistance.

FIG. 3 is a schematic cross sectional view showing the semiconductor device 1 according to the first embodiment. FIG. 3 is a cross sectional view taken along a line B-B shown in FIG. 2. The line B-B shown in FIG. 2 is inside the termination region and also inside the 2nd P+ region.

The semiconductor device 1 further includes a seventh insulation film 71 and an eighth insulation film 73.

The seventh insulation film 71 functions as a gate insulation film together with the first insulation film 41. Making the gate insulation film thicker in the termination region can improve the avalanche resistance to make the element less likely to break even if the potential rises.

The seventh insulation film 71 has a first portion located between the first controller 40A and the first insulation film 41, a second portion located between the second controller 40B and the first insulation film 41, and a third portion located between the second insulation film 43 and the fourth insulation film 55.

The eighth insulation film 73 is provided between the seventh insulation film 71 and the fifth insulation film 57. The eighth insulation film 73 is, for example, a BPSG (boron phosphorus silicate glass) film.

As shown in FIG. 3, the distance between the second semiconductor layer 13, which is in contact with the fourth semiconductor layer 17, and the first electrode 20, in the termination region is smaller than the distance between the second semiconductor layer 13, which is in contact with the fourth semiconductor layer 17, and the first electrode 20, in the cell region. Also, the front surface side of the first semiconductor layer 11, which faces the fourth semiconductor layer 17 in the Z direction, in the termination region, is located closer to the back surface side than the front surface side of the first semiconductor layer 11, which faces the fourth semiconductor layer 17 in the Z direction, in the cell region. This makes it possible to improve the avalanche resistance in the termination region near the third semiconductor layer 15 while preventing a rise in on-resistance.

More specifically, the second semiconductor layer 13, which is located on the back surface side of the fourth semiconductor layer 17 in the termination region, extends into the first semiconductor layer 11. The second semiconductor layer 13, which is located on the back surface side of the fourth semiconductor layer 17 in the termination region, extends so as to protrude by about 1 nm into the first semiconductor layer 11, for example. Contrarily, the second semiconductor layer 13, which is located on the back surface side of the fourth semiconductor layer 17 in the cell region, does not extend into the first semiconductor layer 11 (see FIG. 1).

As described above, according to the first embodiment, the distance between the second semiconductor layer 13, which is in contact with the fourth semiconductor layer 17, and the first electrode 20, in the termination region is smaller than the distance between the second semiconductor layer 13, which is in contact with the fourth semiconductor layer 17, and the first electrode 20, in the cell region. This makes it possible to improve the avalanche resistance in the termination region near the third semiconductor layer 15 while preventing a rise in on-resistance.

The impurity concentration of the portion of the second semiconductor layer 13 protruding into the first semiconductor layer 11 does not necessarily have to be the same as the impurity concentration of the second semiconductor layer 13. In other words, the protruding portion may be another semiconductor layer of the second conductivity type.

### Modification

In a modification of the first embodiment, the contact trench CT does not need to be provided. In this case, the fourth semiconductor layer 17 is located at substantially the same level as the third semiconductor layer 15 in the Z direction.

As in the modification of the first embodiment, the contact trench CT does not need to be provided. The semiconductor device according to the modification of the first embodiment can obtain the same effect as the first embodiment.

### Second Embodiment

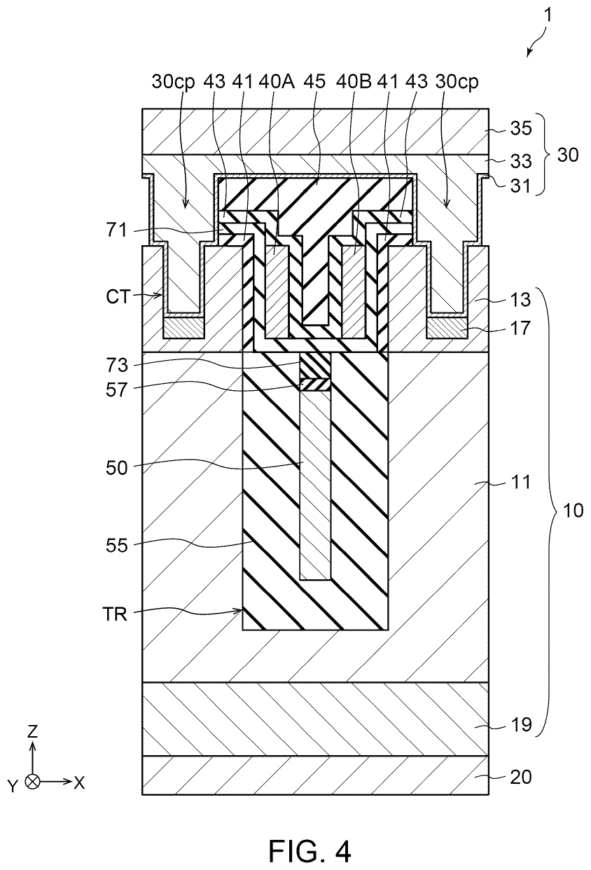

FIG. 4 is a schematic cross sectional view showing a semiconductor device 1 according to a second embodiment. In the second embodiment, the concentration of the second conductivity type impurity in the fourth semiconductor layer 17 is different from that in the first embodiment.

The concentration of the second conductivity type impurity in the fourth semiconductor layer 17 in the termination region is different from the concentration of the second conductivity type impurity in the fourth semiconductor layer 17 in the cell region. More specifically, the concentration of the second conductivity type impurity in the fourth semiconductor layer 17 in the termination region is higher than the concentration of the second conductivity type impurity in the fourth semiconductor layer 17 in the cell region. This makes it possible to improve the avalanche resistance in the termination region near the third semiconductor layer 15 while preventing a rise in on-resistance. The concentration of the second conductivity type impurity in the fourth semiconductor layer 17 in the termination region is, for example, twice the concentration of the second conductivity type impurity in the fourth semiconductor layer 17 in the cell region. In this case, the concentration of the second conductivity type impurity in the fourth semiconductor layer 17 in the termination region is, for example, 3×10¹⁹ (atoms/cm³), and the concentration of the second conductivity type impurity in the fourth semiconductor layer 17 in the cell region is, for example, 6×10¹⁹ (atoms/cm³).

The size of the fourth semiconductor layer 17 in the termination region may be larger than the size of the fourth semiconductor layer 17 in the cell region.

As in the modification of the first embodiment, the concentration of the second conductivity type impurity in the fourth semiconductor layer 17 may be changed. The semiconductor device according to the second embodiment can obtain the same effects as the first embodiment. The semiconductor device according to the second embodiment may be combined with the first embodiment. In this case, in the termination region, the shapes of the first semiconductor layer 11 and the second semiconductor layer 13 according to the first embodiment are combined with the concentration of the fourth semiconductor layer 17 according to the second embodiment.

### Third Embodiment

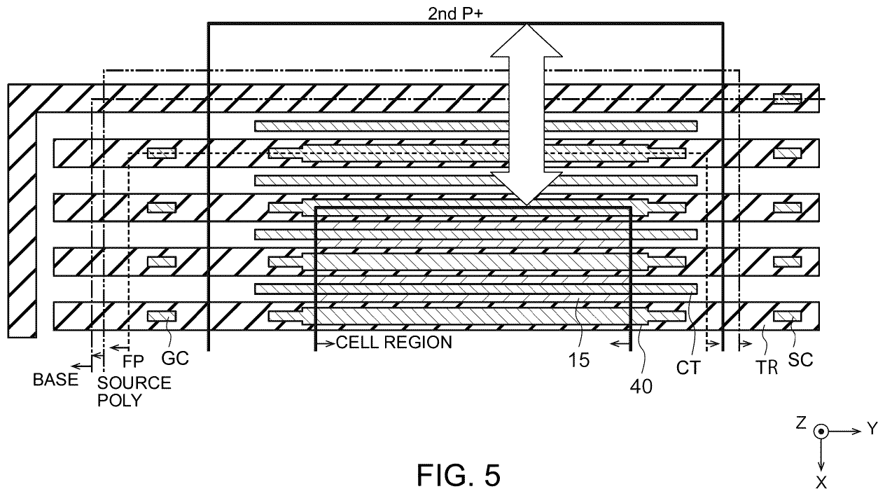

FIG. 5 is a schematic layout diagram showing a semiconductor device 1 according to a third embodiment. The third embodiment differs from the first embodiment in that the third embodiment is not provided with a 2nd FP region.

In the third embodiment, the seventh insulation film 71 shown in FIG. 3 is not provided. As explained in the first embodiment, the seventh insulation film 71 is provided to improve the avalanche resistance. Since the structure shown in FIG. 3 improves the avalanche resistance, the seventh insulation film 71 can be omitted.

As in the modification of the third embodiment, the 2nd FP region does not need to be provided. The semiconductor device according to the third embodiment can obtain the same effect as the first embodiment. The semiconductor device according to the third embodiment may be combined with the second embodiment.

### Fourth Embodiment

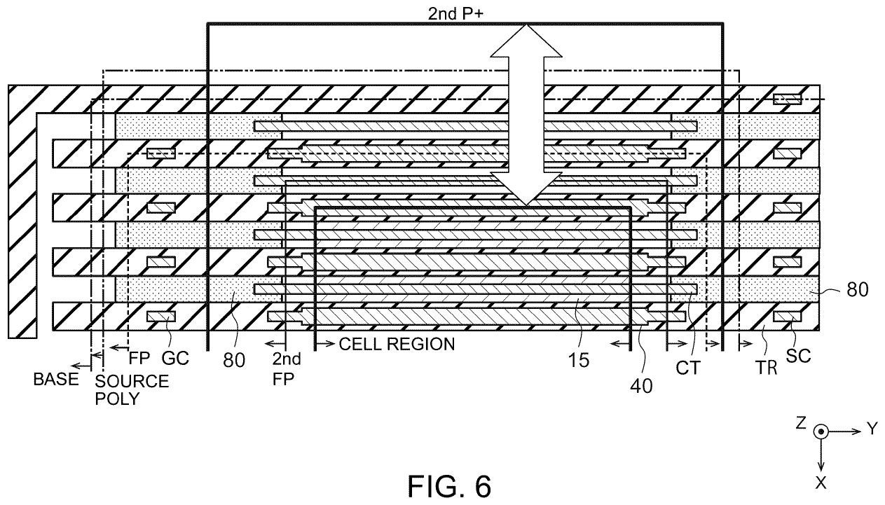

FIG. 6 is a schematic layout diagram showing a semiconductor device 1 according to a fourth embodiment. The fourth embodiment differs from the first embodiment in that the fourth embodiment is provided with a p-type high concentration layer 80.

The p-type high concentration layer 80 (sixth semiconductor layer) is provided on the front surface side of the semiconductor area 10. As explained in the first embodiment, the p-type high concentration layer 80 is provided to prevent the operation of the parasitic bipolar transistor to improve the avalanche resistance. The p-type high concentration layer 80 (sixth semiconductor layer) can therefore further improve the avalanche resistance in the termination region.

As in the fourth embodiment, the p-type high concentration layer 80 may be provided. The semiconductor device according to the fourth embodiment can obtain the same effect as the first embodiment. The semiconductor device according to the fourth embodiment may also be combined with the second embodiment and the third embodiment.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

1. A semiconductor device, comprising:
a semiconductor area including a first semiconductor layer of a first conductivity type and a second semiconductor layer of a second conductivity type;
a first electrode provided on a back surface of the semiconductor area;
a second electrode provided on a front surface of the semiconductor area, the first semiconductor layer extending between the first electrode and the second electrode, the second semiconductor layer being provided between the first semiconductor layer and the second electrode;
a control electrode provided within the semiconductor area; and
a third electrode located between the control electrode and the first electrode in a first direction from the first electrode toward the second electrode, wherein
the semiconductor area in a first region further includes a third semiconductor layer of the first conductivity type, the third semiconductor layer being provided between the second semiconductor layer and the second electrode,
the semiconductor area further includes a fourth semiconductor layer of the second conductivity type, the fourth semiconductor layer being provided between the second semiconductor layer and the second electrode, and being electrically connected to the second electrode, and
a distance between the second semiconductor layer and the first electrode in a second region surrounding the first region is smaller than a distance between the second semiconductor layer and the first electrode in the first region, the second semiconductor layer being in contact with the fourth semiconductor layer both in the first region and the second region.

2. The semiconductor device according to claim 1, wherein
the second semiconductor layer, located on the back surface side of the fourth semiconductor layer, extends into the first semiconductor layer, in the second region, and
the second semiconductor layer, located on the back surface side of the fourth semiconductor layer, does not extend into the first semiconductor layer, in the first region.

3. The semiconductor device according to claim 1, wherein a concentration of the second conductivity type impurity of the fourth semiconductor layer in the second region is different from a concentration of the second conductivity type impurity of the fourth semiconductor layer in the first region.

4. The semiconductor device according to claim 3, wherein a concentration of the second conductivity type impurity of the fourth semiconductor layer in the second region is higher than a concentration of the second conductivity type impurity of the fourth semiconductor layer in the first region.

5. A semiconductor device, comprising:
a semiconductor area including a first semiconductor layer of a first conductivity type and a second semiconductor layer of a second conductivity type;
a first electrode provided on a back surface of the semiconductor area;
a second electrode provided on a front surface of the semiconductor area, the first semiconductor layer extending between the first electrode and the second electrode, the second semiconductor layer being provided between the first semiconductor layer and the second electrode;
a control electrode provided within the semiconductor area; and
a third electrode located between the control electrode and the first electrode in a first direction from the first electrode toward the second electrode, wherein
the semiconductor area in a first region further includes a third semiconductor layer of the first conductivity type, the third semiconductor layer being provided between the second semiconductor layer and the second electrode,
the semiconductor area further includes a fourth semiconductor layer of the second conductivity type, the fourth semiconductor layer being provided between the second semiconductor layer and the second electrode, and being electrically connected to the second electrode, and
a concentration of the second conductivity type impurity of the fourth semiconductor layer in a second region surrounding the first region is different from a concentration of the second conductivity type impurity of the fourth semiconductor layer in the first region.

6. The semiconductor device according to claim 5, wherein a concentration of the second conductivity type impurity of the fourth semiconductor layer in the second region is higher than a concentration of the second conductivity type impurity of the fourth semiconductor layer in the first region.

7. The semiconductor device according to claim 1, wherein
the second electrode includes a contactor, the contactor being provided inside a trench having a depth from the front surface side of the semiconductor area into the second semiconductor layer, the contactor extending from the front surface side of the semiconductor area into the second semiconductor layer, and
the fourth semiconductor layer is provided between the second semiconductor layer and the contactor and is electrically connected to the contactor.

8. The semiconductor device according to claim 2, wherein
the second electrode includes a contactor, the contactor being provided inside a trench having a depth from the front surface side of the semiconductor area into the second semiconductor layer, the contactor extending from the front surface side of the semiconductor area into the second semiconductor layer, and
the fourth semiconductor layer is provided between the second semiconductor layer and the contactor and is electrically connected to the contactor.

9. The semiconductor device according to claim 3, wherein
the second electrode includes a contactor, the contactor being provided inside a trench having a depth from the front surface side of the semiconductor area into the second semiconductor layer, the contactor extending from the front surface side of the semiconductor area into the second semiconductor layer, and
the fourth semiconductor layer is provided between the second semiconductor layer and the contactor and is electrically connected to the contactor.

10. The semiconductor device according to claim 4, wherein
the second electrode includes a contactor, the contactor being provided inside a trench having a depth from the front surface side of the semiconductor area into the second semiconductor layer, the contactor extending from the front surface side of the semiconductor area into the second semiconductor layer, and
the fourth semiconductor layer is provided between the second semiconductor layer and the contactor and is electrically connected to the contactor.

11. The semiconductor device according to claim 5, wherein
the second electrode includes a contactor, the contactor being provided inside a trench having a depth from the front surface side of the semiconductor area into the second semiconductor layer, the contactor extending from the front surface side of the semiconductor area into the second semiconductor layer, and
the fourth semiconductor layer is provided between the second semiconductor layer and the contactor and is electrically connected to the contactor.

12. The semiconductor device according to claim 6, wherein
the second electrode includes a contactor, the contactor being provided inside a trench having a depth from the front surface side of the semiconductor area into the second semiconductor layer, the contactor extending from the front surface side of the semiconductor area into the second semiconductor layer, and
the fourth semiconductor layer is provided between the second semiconductor layer and the contactor and is electrically connected to the contactor.

13. The semiconductor device according to claim 1, wherein the fourth semiconductor layer is located at substantially the same level as the third semiconductor layer in the first direction.

14. The semiconductor device according to claim 2, wherein the fourth semiconductor layer is located at substantially the same level as the third semiconductor layer in the first direction.

15. The semiconductor device according to claim 3, wherein the fourth semiconductor layer is located at substantially the same level as the third semiconductor layer in the first direction.

16. The semiconductor device according to claim 4, wherein the fourth semiconductor layer is located at substantially the same level as the third semiconductor layer in the first direction.

17. The semiconductor device according to claim 5, wherein the fourth semiconductor layer is located at substantially the same level as the third semiconductor layer in the first direction.

18. The semiconductor device according to claim 6, wherein the fourth semiconductor layer is located at substantially the same level as the third semiconductor layer in the first direction.
